(19) United States
(12) Patent Application Publication
(10) Pub. No.: US 2026/0282304 A1
(43) Pub. Date: Sep. 17, 2026

(54) VEHICLE ON-BOARD ELECTRICAL DEVICE

(71) Applicant: KABUSHIKI KAISHA TOYOTA JIDOSHOKKI, Aichi-ken (JP)

(72) Inventors: Yusuke SHINTANI, Kariya-shi (JP); Yuma SATO, Kariya-shi (JP)

(73) Assignee: KABUSHIKI KAISHA TOYOTA JIDOSHOKKI, Aichi-ken (JP)

(21) Appl. No.: 19/560,684

(22) Filed: Mar. 9, 2026

(30) Foreign Application Priority Data
Mar. 11, 2025 (JP) 2025-038586

(51) Int. Cl. H05K 9/00; B60R 16/023; B60R 16/033; H05K 5/00

(52) U.S. Cl. CPC H05K 9/0022; B60R 16/0231; B60R 16/033; H05K 5/0069

(57) ABSTRACT

A vehicle on-board electrical device includes a circuit board accommodated inside a housing, an electronic component including a component body and a component terminal, a housing connector including a housing connector body and a housing connector terminal, and a shield member made of a metal plate. A conductor pattern forming an electrical circuit is formed on the circuit board. The housing connector body is provided on the housing so as to allow an external connector to be connected to the housing connector body from outside the housing. The component terminal includes a first electrical connection portion electrically connected to the conductor pattern. The housing connector terminal includes a second electrical connection portion electrically connected to the conductor pattern. In the housing connector, at least the second electrical connection portion of the housing connector terminal is covered by the shield member.

### CROSS-REFERENCE TO RELATED APPLICATIONS

This application is based upon and claims the benefit of priority from Japanese Patent Application No. 2025-038586, filed on Mar. 11, 2025, the entire contents of which are incorporated herein by reference.

### BACKGROUND

### 1. Field

The present disclosure relates to a vehicle on-board electrical device.

### 2. Description of Related Art

Vehicles such as battery electric vehicles are equipped with vehicle on-board electrical devices, for example, as disclosed in JPH08-88055A. Such a vehicle on-board electrical device includes a box-shaped housing, a circuit board, an electronic component, and a housing connector. The circuit board is accommodated within the housing. Conductor patterns forming electrical circuits are formed on the circuit board. The electronic component includes a component body and component terminals. The component body may function as a component of an electrical circuit. The component terminals mount the component body to a conductor pattern. The electronic component generates electromagnetic noise. The housing connector includes a housing connector body and housing connector terminals. The housing connector body is provided on the housing so as to allow an external connector to be connected to the housing connector body from outside the housing. The housing connector terminals mount the housing connector body to a conductor pattern. The component terminals and the housing connector terminals each include an electrical connection portion that is electrically connected to the corresponding conductor pattern.

In the vehicle on-board electrical device disclosed in the above publication, the housing connector body is covered by a shield member; however, electrical connection portions located on the opposite side of the circuit board from the housing connector body are not covered by a shield member. As a result, electromagnetic noise generated by the electronic component may propagate to the electrical connection portions and may leak to the external connector via the housing connector terminals. In addition, electromagnetic noise entering from the external connector may propagate to the electrical connection portions, and electromagnetic noise may be radiated from the electrical connection portions within the housing.

An objective of the present disclosure is to suppress leakage of electromagnetic noise from the electrical connection portions to the external connector and to suppress radiation, within the housing, of electromagnetic noise that enters from the external connector via the electrical connection portions.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a vehicle on-board electrical device includes a box-shaped housing, a circuit board accommodated in the housing, an electronic component having a component body and a component terminal, and a housing connector including a housing connector body and a housing connector terminal. A conductor pattern forming an electrical circuit is formed on the circuit board. Electromagnetic noise is radiated from the electronic component. The component body is configured to function as a component of the electrical circuit. The component terminal is configured to mount the component body to the conductor pattern. The housing connector body is provided on the housing so as to allow an external connector to be connected to the housing connector body from outside the housing. The housing connector terminal is configured to mount the housing connector body to the conductor pattern. The component terminal includes a first electrical connection portion electrically connected to the conductor pattern. The housing connector terminal includes a second electrical connection portion electrically connected to the conductor pattern. The vehicle on-board electrical device further comprises a shield member made of a metal plate. In the housing connector, at least the second electrical connection portion of the housing connector terminal is covered by the shield member.

Other features and aspects will be apparent from the following detailed description, the drawings, and the claims.

### BRIEF DESCRIPTION OF THE DRAWINGS

FIG. 1 is a cross-sectional view of a vehicle on-board electrical device according to an embodiment.

FIG. 2 is an enlarged cross-sectional view illustrating part of the vehicle on-board electrical device shown in FIG. 1.

FIG. 3 is a cross-sectional view illustrating part of a vehicle on-board electrical device according to a first modification.

FIG. 4 is a cross-sectional view illustrating part of a vehicle on-board electrical device according to a second modification.

FIG. 5 is a cross-sectional view illustrating part of a vehicle on-board electrical device according to a third modification.

FIG. 6 is a cross-sectional view illustrating part of a vehicle on-board electrical device according to a fourth modification.

FIG. 7 is a cross-sectional view illustrating part of a vehicle on-board electrical device according to a fifth modification.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

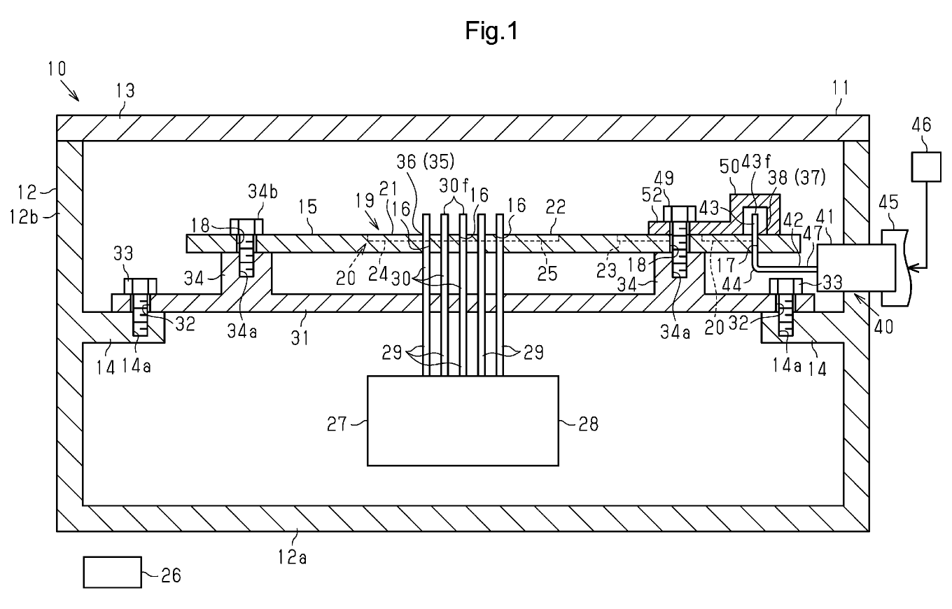

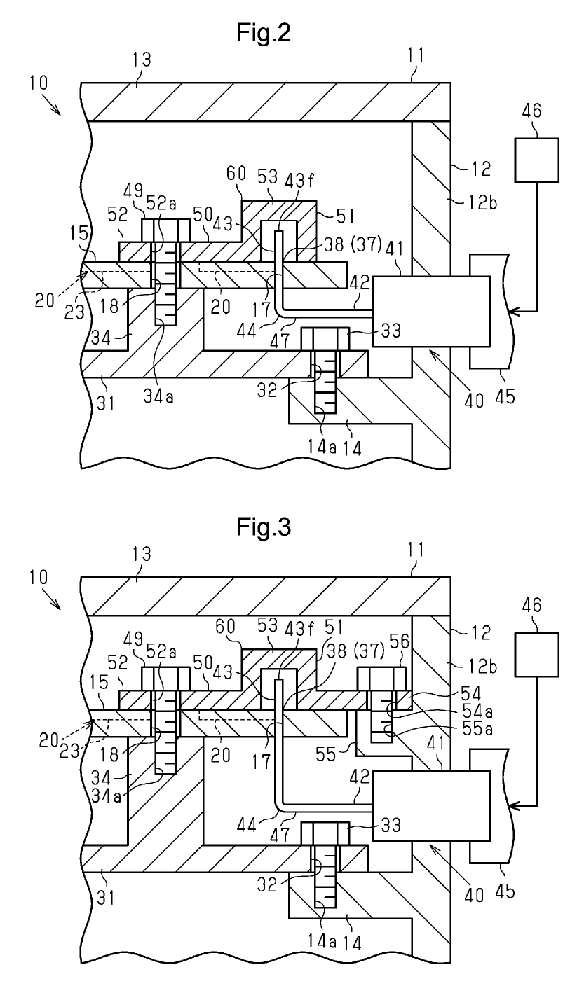

A vehicle on-board electrical device 10 according to an embodiment will now be described with reference to FIGS. 1 and 2. The vehicle on-board electrical device 10 of the present embodiment is mounted on a vehicle such as a battery electric vehicle.

### Housing

As shown in FIG. 1, the vehicle on-board electrical device 10 includes a housing 11. The housing 11 is box-shaped. The housing 11 is made of metal. The housing 11 is made of, for example, aluminum. The housing 11 is connected to ground, which may be, for example, a vehicle body. The housing 11 includes a housing body 12 and a lid member 13. The housing body 12 includes a plate-shaped end wall 12a and a peripheral wall 12b. The housing body 12 includes an opening on a side opposite to the end wall 12a. The peripheral wall 12b extends from the outer periphery of the end wall 12a. The lid member 13 has the shape of a plate. The lid member 13 covers the opening of the housing body 12.

The housing 11 includes multiple support portions 14. Each support portion 14 protrudes from the inner surface of the peripheral wall 12b. Each support portion 14 is beam-shaped. Each support portion 14 includes an internal thread hole 14a.

### Circuit Board

The vehicle on-board electrical device 10 includes a circuit board 15. The circuit board 15 has the shape of a flat plate. The circuit board 15 has a first surface and a second surface. The circuit board 15 is accommodated in the housing 11 so as to extend parallel to the lid member 13. The circuit board 15 is accommodated in the housing 11 such that the first surface faces the lid member 13. The circuit board 15 has multiple first lead insertion holes 16. In the present embodiment, the circuit board 15 has five first lead insertion holes 16. Each of the first lead insertion holes 16 extends through the circuit board 15 in the thickness direction of the circuit board 15. The circuit board 15 includes second lead insertion holes 17. The second lead insertion holes 17 extend through the circuit board 15 in the thickness direction of the circuit board 15. The circuit board 15 includes multiple bolt insertion holes 18. Each of the bolt insertion holes 18 extends through the circuit board 15 in the thickness direction of the circuit board 15.

### Conductor Patterns

Conductor patterns 20 forming electrical circuits 19 are formed on the circuit board 15. The electrical circuits 19 include a high-voltage circuit section 21 and a low-voltage circuit section 22. The high-voltage circuit section 21 is connected to a high-voltage battery 26. The low-voltage circuit section 22 has a lower voltage than the high-voltage circuit section 21.

The conductor patterns 20 include a ground pattern section 23, a high-voltage pattern section 24, and a low-voltage pattern section 25. The high-voltage pattern section 24 forms the high-voltage circuit section 21. The low-voltage pattern section 25 forms the low-voltage circuit section 22. The high-voltage pattern section 24 and the low-voltage pattern section 25 are insulated from each other on the first surface of the circuit board 15.

### Electronic Component

The vehicle on-board electrical device 10 includes an electronic component 27. The electronic component 27 is accommodated in the housing 11. The electronic component 27 includes a component body 28 and component terminals 29. The component body 28 has the shape of a rectangular block. The component body 28 may function as a component of the electrical circuits 19.

The component terminals 29 project from the component body 28. In the present embodiment, the electronic component 27 includes five component terminals 29. Three of the five component terminals 29 are high-voltage terminals, which are thin plate-shaped component leads 30 connecting the component body 28 to the high-voltage pattern section 24. The remaining two of the five component terminals 29 are low-voltage terminals, which are thin plate-shaped leads connecting the component body 28 to the low-voltage pattern section 25. In this manner, the component terminals 29 mount the component body 28 to the conductor pattern 20. The five component terminals 29 protrude from one surface of the component body 28 while being aligned in a single direction. Accordingly, the electronic component 27 is a discrete semiconductor element. The electronic component 27 is a switching element. Therefore, the electronic component 27 is a power semiconductor element. The electronic component 27 generates electromagnetic noise.

### Shield Plate

The vehicle on-board electrical device 10 includes a shield plate 31. The shield plate 31 has the shape of a flat plate. The shield plate 31 is made of metal. Accordingly, the shield plate 31 is a metal plate. The shield plate 31 is disposed between the component body 28 of the electronic component 27 and the circuit board 15. The shield plate 31 is accommodated in the housing 11 in a state in which the thickness direction of the shield plate 31 agrees with the thickness direction of the circuit board 15.

The shield plate 31 includes multiple bolt insertion holes 32. The bolt insertion holes 32 extend through the shield plate 31 in the thickness direction of the shield plate 31. The shield plate 31 is disposed on the support portions 14 in a state in which the bolt insertion holes 32 respectively communicate with the internal thread holes 14a of the support portions 14. The shield plate 31 is supported by the support portions 14 with bolts 33 respectively inserted into the bolt insertion holes 32 and screwed into the internal thread holes 14a of the support portions 14. Accordingly, the shield plate 31 is connected to the housing 11 via the bolts 33. As a result, the shield plate 31 is connected to ground.

The shield plate 31 extends along the circuit board 15. Accordingly, the shield plate 31 is disposed between the component body 28 of the electronic component 27 and the circuit board 15, extends along the circuit board 15, and is connected to ground. The shield plate 31 is disposed at a position overlapping with the circuit board 15 in the thickness direction of the circuit board 15. Accordingly, the shield plate 31 faces the circuit board 15. The shield plate 31 is separate from the housing 11.

The shield plate 31 includes multiple bosses 34. Each boss 34 protrudes toward the circuit board 15 from the surface of the shield plate 31 facing the circuit board 15. A distal end face of each boss 34 is in contact with the circuit board 15. An internal thread hole 34a is formed in the distal end face of each boss 34. The circuit board 15 is disposed on the bosses 34 in a state in which the bolt insertion holes 18 respectively communicate with the internal thread hole 34a of the bosses 34. The circuit board 15 is fixed to the bosses 34 by inserting bolts 34b respectively into the bolt insertion holes 18 and screwing the bolts 34b into the internal thread holes 34a of the bosses 34.

### High-Voltage Solder Portions

The five component terminals 29 are provided so as not to interfere with the shield plate 31. Accordingly, the component leads 30 are provided so as not to interfere with the shield plate 31. The component terminals 29 are respectively inserted into the first lead insertion holes 16. The component terminals 29 are soldered to the conductor patterns 20 on a first-surface side of the circuit board 15. Therefore, each component terminal 29 has a solder portion 35 soldered to the corresponding conductor pattern 20.

The five component terminals 29 extend through the circuit board 15 from the second surface toward the first surface of the circuit board 15. In other words, the component terminals 29 extend through the circuit board 15 from the side opposite to the side on which the solder portions 35 of the component terminals 29 are located toward the side on which the solder portions 35 are located. Accordingly, the component leads 30 extend through the circuit board 15 from the side opposite to the side on which the solder portions 35 of the component terminals 29 are located toward the side on which the solder portions 35 are located. Each component lead 30 includes a component lead projection 30f that projects beyond the high-voltage pattern section 24 in a direction from the second surface toward the first surface of the circuit board 15. Each component lead projection 30f includes a high-voltage solder portion 36 soldered to the high-voltage pattern section 24.

### Housing Connector

The vehicle on-board electrical device 10 includes a housing connector 40. The housing connector 40 includes a housing connector body 41 and housing connector terminals 42. The housing connector body 41 is provided on the peripheral wall 12b of the housing 11. The housing connector body 41 is provided in the housing 11 so that an external connector 45 can be connected to the housing connector body 41 from outside the housing 11.

The housing connector terminals 42 are thin plate-shaped connector leads 43 that connect the housing connector body 41 to the corresponding conductor pattern 20. The connector leads 43 are inserted into the second lead insertion holes 17. The connector leads 43 extend through the circuit board 15 from the second surface toward the first surface of the circuit board 15. Specifically, the connector leads 43 extend through the circuit board 15 from the side opposite to the side on which the solder portions 35 of the component terminals 29 are located toward the side on which the solder portions 35 are located. Each connector lead 43 includes a connector projection 43f that projects beyond the corresponding conductor pattern 20 in the direction from the second surface toward the first surface of the circuit board 15.

Each connector lead 43 includes a bent portion 44 on a second-surface side of the circuit board 15. The bent portion 44 extends from the housing connector body 41 toward the connector projection 43f. The bent portion 44 is bent on the second-surface side of the circuit board 15. The housing connector terminals 42 include a communication line 47 for communicating with an external higher-level ECU 46 connected to the external connector 45. The housing connector terminals 42 may include a power line (not shown) connected to a vehicle on-board battery or a signal line (not shown) for a purpose different from that of the communication line 47.

### Low-Voltage Solder Portions

The housing connector terminals 42 are soldered to the corresponding conductor pattern 20 on the first-surface side of the circuit board 15. Therefore, each housing connector terminal 42 has a solder portion 37 soldered to the corresponding conductor pattern 20. Accordingly, the component terminals 29 and the housing connector terminals 42 each include electrical connection portions that are electrically connected to the corresponding conductor pattern 20. The electrical connection portions are solder portions 35, 37 soldered to the conductor patterns 20.

The solder portions 37 of the housing connector terminals 42 are portions of the connector projections 43f that are soldered to the corresponding conductor pattern 20. The connector projections 43f of the housing connector terminals 42 each include a low-voltage solder portion 38 soldered to the low-voltage pattern section 25. In this manner, the housing connector terminals 42 mount the housing connector body 41 to the corresponding conductor pattern 20.

### Shield Member

As shown in FIG. 2, the vehicle on-board electrical device 10 includes a shield member 50. The shield member 50 is made of a metal plate. The shield member 50 includes a covering portion 51 and a fastened portion 52. The covering portion 51 includes a shield projection 53. The shield projection 53 projects in a direction away from the corresponding conductor pattern 20 so as to accommodate the solder portions 37 of the housing connector terminals 42. In this manner, the covering portion 51 covers the solder portions 37 of the housing connector terminals 42. Accordingly, in the housing connector 40, at least the solder portions 37 of the housing connector terminals 42 are covered by the shield member 50. Thus, the shield member 50 includes a solder portion shield section 60 that covers the solder portions 37 of the housing connector terminals 42.

The fastened portion 52 extends from the covering portion 51. The fastened portion 52 includes a bolt insertion hole 52a. The bolt insertion hole 52a extends through the fastened portion 52 in the thickness direction of the fastened portion 52. The shield member 50 is disposed on the circuit board 15 such that the bolt insertion hole 52a communicates with one of the bolt insertion holes 18 in the circuit board 15. The fastened portion 52 and the ground pattern section 23 are electrically connected to each other.

The shield member 50 is fastened to the circuit board 15 by inserting a bolt 49 through the bolt insertion hole 52a in the fastened portion 52 and the corresponding bolt insertion hole 18 in the circuit board 15 and screwing the bolt 49 into the internal thread hole 34a of one of the bosses 34 of the shield plate 31. Therefore, the fastened portion 52 of the shield member 50 is fastened to the housing 11 via the circuit board 15 and the shield plate 31. Accordingly, the fastened portion 52 is fastened to the housing 11 together with the ground pattern section 23 included in the conductor patterns 20.

### Operation of the Embodiment

Operation of the present embodiment will now be described.

The shield plate 31 is disposed between the component body 28 of the electronic component 27 and the circuit board 15. Therefore, noise radiated from the component body 28 of the electronic component 27 toward the circuit board 15 is blocked by the shield plate 31. The noise blocked by the shield plate 31 is conducted to ground through the respective bolts 33 and the housing 11.

In a case in which the electronic component 27 is a discrete semiconductor element having multiple component terminals 29 including both high-voltage terminals and low-voltage terminals, the component leads 30, which are high-voltage terminals, are electrically connected to the circuit board 15. Therefore, it is difficult for the shield plate 31 to block electromagnetic noise radiated from the component leads 30 toward the solder portions 37 of the housing connector terminals 42.

In the housing connector 40 according to the present embodiment, at least the solder portions 37 of the housing connector terminals 42 are covered by the shield member 50, made of a metal plate. Therefore, electromagnetic noise generated by the component leads 30 is blocked by the shield member 50. In addition, even when electromagnetic noise enters the housing connector 40 from the external connector 45, the shield member 50 blocks the electromagnetic noise traveling from the solder portions 37 of the housing connector terminals 42 toward the inside of the housing 11.

The fastened portion 52 of the shield member 50 is fastened to the housing 11 together with the ground pattern section 23 included in the conductor patterns 20. Therefore, electromagnetic noise blocked by the shield member 50 flows to the ground pattern section 23 via the fastened portion 52. As a result, leakage of electromagnetic noise to the external connector 45 is suppressed, and electromagnetic noise that has entered the housing connector 40 from the external connector 45 is suppressed from being radiated to the inside of the housing 11 from the solder portions 37 of the housing connector terminals 42.

### Advantages of the Embodiment

The above-described embodiment has the following advantages.

(1) In the housing connector 40, at least the solder portions 37 of the housing connector terminals 42 are covered by the shield member 50, made of a metal plate. Therefore, electromagnetic noise generated by the electronic component 27 is blocked by the shield member 50. In addition, even when electromagnetic noise enters the housing connector 40 from the external connector 45, the shield member 50 blocks the electromagnetic noise traveling from the solder portions 37 of the housing connector terminals 42 toward the inside of the housing 11. As a result, leakage of electromagnetic noise from the solder portions 37 to the external connector 45 is suppressed, and electromagnetic noise entering from the external connector 45 is suppressed from being radiated from the solder portions 37 inside the housing 11.

(2) The solder portions 37 of the housing connector terminals 42 are accommodated in the shield projection 53. The connector leads 43 extend through the circuit board 15 from the second surface toward the first surface of the circuit board 15. Specifically, the connector leads 43 extend through the circuit board 15 from the side opposite to the side on which the solder portions 35 of the component terminals 29 are located toward the side on which the solder portions 35 are located. The connector projections 43f of the connector leads 43 project beyond the corresponding conductor pattern 20 in the direction from the second surface toward the first surface of the circuit board 15. Even in this case, the shield member 50 covers the solder portions 37 of the housing connector terminals 42.

(3) The housing connector terminals 42 include the communication line 47 for communicating with the external higher-level ECU 46 connected to the external connector 45. Even in this case, since the electromagnetic noise generated by the electronic component 27 is blocked by the shield member 50, leakage of the electromagnetic noise to the external connector 45 via the communication line 47 is suppressed. As a result, adverse effects of electromagnetic noise on the external higher-level ECU 46 are suppressed.

(4) The shield member 50 includes the fastened portion 52, which is fastened to the housing 11 together with the ground pattern section 23 included in the conductor patterns 20. Accordingly, for example, as compared with a case in which the fastened portion 52 is fastened to the housing 11 separately from the ground pattern section 23, an increase in size of the circuit board 15 is limited.

(5) The component lead projection 30f of each component lead 30 includes a high-voltage solder portion 36 soldered to the high-voltage pattern section 24. The connector projections 43f of the housing connector terminals 42 each include a low-voltage solder portion 38 soldered to the low-voltage pattern section 25. In this case, electromagnetic noise radiated from the high-voltage solder portions 36 toward the low-voltage solder portions 38 is blocked by the solder portion shield section 60. As a result, leakage of the electromagnetic noise to the external connector 45 is further suppressed.

(6) The shield plate 31 is disposed between the component body 28 of the electronic component 27 and the circuit board 15. According to this configuration, electromagnetic noise radiated from the component body 28 of the electronic component 27 toward the circuit board 15 is blocked by the shield plate 31. As a result, leakage of electromagnetic noise from the solder portions 37 to the external connector 45 is further suppressed.

### Modifications

The above-described embodiment may be modified as follows. The above-described embodiment and the following modifications can be combined as long as the combined modifications remain technically consistent with each other.

FIG. 3 shows a vehicle on-board electrical device according to a first modification. As shown in FIG. 3, the shield member 50 may have an extending fastened portion 54. The extending fastened portion 54 extends from the fastened portion 52, specifically, from the covering portion 51, toward the peripheral wall 12b of the housing 11. The fastened portion 52 is a first fastened portion, and the extending fastened portion 54 is a second fastened portion. The extending fastened portion 54 has the shape of a plate. The thickness direction of the extending fastened portion 54 agrees with the thickness direction of the fastened portion 52. The extending fastened portion 54 includes a bolt insertion hole 54a. The bolt insertion hole 54a extends through the extending fastened portion 54 in the thickness direction of the extending fastened portion 54.

A fixing portion 55 is provided on the peripheral wall 12b of the housing 11. The fixing portion 55 protrudes from the inner surface of the peripheral wall 12b. The fixing portion 55 includes an internal thread hole 55a. The extending fastened portion 54 is disposed on the fixing portion 55 such that the bolt insertion hole 54a communicates with the internal thread hole 55a. The extending fastened portion 54 is fixed to the fixing portion 55 by inserting a bolt 56 into the bolt insertion hole 54a and screwing the bolt 56 into the internal thread hole 55a. In this manner, the extending fastened portion 54 is fastened to the housing 11 with the bolt 56.

This configuration causes electromagnetic noise blocked by the shield member 50 to flow to the housing 11 via the extending fastened portion 54. As a result, leakage of electromagnetic noise from the solder portions 37 to the external connector 45 is suppressed more reliably, and electromagnetic noise entering from the external connector 45 is suppressed more reliably from being radiated from the solder portions 37 inside the housing 11.

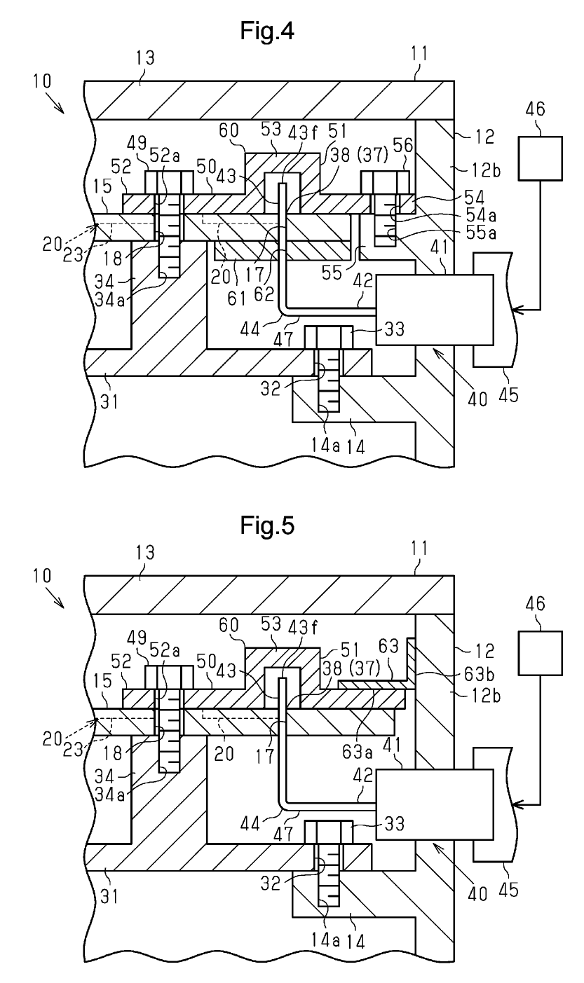

FIG. 4 shows a vehicle on-board electrical device according to a second modification. As shown in FIG. 4, the shield member 50 may include a solder portion shield section 60 and a bent portion shield section 61. The bent portion shield section 61 is made of a metal plate. The bent portion shield section 61 includes through-holes 62. The through-holes 62 extend through the bent portion shield section 61 in the thickness direction of the bent portion shield section 61. The solder portion shield section 60 is provided on the opposite side of the circuit board 15 from the bent portion shield section 61. The bent portion shield section 61 is provided on the second surface of the circuit board 15. That is, the bent portion shield section 61 is provided on the circuit board 15 on the side opposite to the side on which the solder portions 35 of the component terminals 29 are located. The thickness direction of the bent portion shield section 61 agrees with the thickness direction of the circuit board 15.

The bent portions 44 pass through the through-holes 62. The bent portion shield section 61 covers at least part of each bent portion 44. The bent portion shield section 61 is disposed between the circuit board 15 and portions of the bent portions 44 extending along the circuit board 15. A part of the bent portion shield section 61 faces part of the bent portions 44 extending along the circuit board 15 in the thickness direction of the circuit board 15. The shield plate 31 is provided on the opposite side of the bent portion shield section 61 from the circuit board 15.

According to this, the solder portion shield section 60 blocks electromagnetic noise radiated from the electronic component 27 toward the solder portions 37 of the housing connector terminals 42. Further, the bent portion shield section 61 blocks at least part of the electromagnetic noise radiated from the electronic component 27 toward the bent portions 44. As a result, leakage of the electromagnetic noise to the external connector 45 is suppressed.

In addition, even when electromagnetic noise enters the housing connector 40 from the external connector 45, the solder portion shield section 60 blocks the electromagnetic noise traveling from the solder portions 37 of the housing connector terminals 42 toward the inside of the housing 11. Further, the bent portion shield section 61 blocks at least part of the electromagnetic noise traveling from the bent portions 44 to the inside of the housing 11. As a result, electromagnetic noise entering from the external connector 45 is suppressed from being radiated inside the housing 11.

FIG. 5 shows a vehicle on-board electrical device according to a third modification. As shown in FIG. 5, the shield member 50 may be connected to the housing 11 via a conductive tape 63. Examples of the conductive tape 63 include a conductive copper foil tape and a conductive aluminum foil tape. The conductive tape 63 includes a first attachment portion 63a attached to the shield member 50 and a second attachment portion 63b attached to the inner surface of the peripheral wall 12b. The first attachment portion 63a is attached to the shield member 50 via a double-sided tape, and the second attachment portion 63b is attached to the inner surface of the peripheral wall 12b via a double-sided tape, so that the shield member 50 is connected to the housing 11 via the conductive tape 63.

This configuration causes electromagnetic noise blocked by the shield member 50 to flow to the housing 11 via the conductive tape 63. As a result, leakage of electromagnetic noise from the solder portions 37 to the external connector 45 is suppressed more reliably, and electromagnetic noise entering from the external connector 45 is suppressed more reliably from being radiated from the solder portions 37 inside the housing 11.

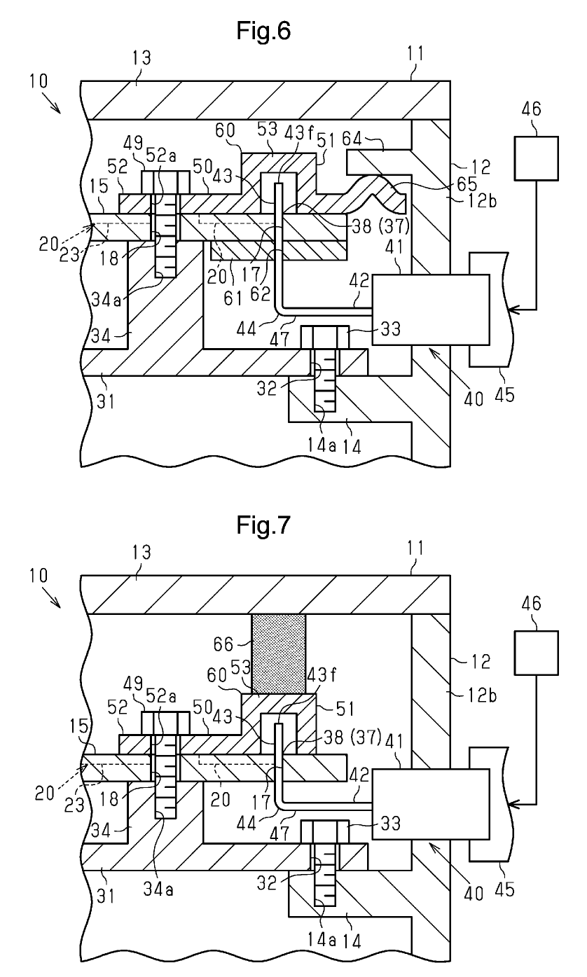

FIG. 6 shows a vehicle on-board electrical device according to a fourth modification. As shown in FIG. 6, the housing 11 may include a protrusion 64 protruding toward the inside of the housing 11, and the shield member 50 may include a spring portion 65 pressed against the protrusion 64. The protrusion 64 protrudes from the inner surface of the peripheral wall 12b toward the shield member 50. The protrusion 64 is formed integrally with the peripheral wall 12b. The spring portion 65 is formed by bending a part of the shield member 50 so as to have a spring property. The spring portion 65 is in contact with the protrusion 64.

This configuration causes electromagnetic noise blocked by the shield member 50 to flow to the housing 11 via the spring portion 65 and the protrusion 64. As a result, leakage of electromagnetic noise from the solder portions 37 to the external connector 45 is suppressed more reliably, and electromagnetic noise entering from the external connector 45 is suppressed more reliably from being radiated from the solder portions 37 inside the housing 11.

FIG. 7 shows a vehicle on-board electrical device according to a fifth modification. As shown in FIG. 7, the shield member 50 may be connected to the lid member 13 via an elastic member 66 having conductivity. The elastic member 66 is, for example, a conductive sponge. The elastic member 66 is interposed between the lid member 13 and the shield projection 53. The elastic member 66 is attached to the inner surface of the lid member 13 via, for example, a double-sided tape. The elastic member 66 is attached to the shield projection 53 via, for example, a double-sided tape.

This configuration causes electromagnetic noise blocked by the shield member 50 to flow to the lid member 13 via the elastic member 66. As a result, leakage of electromagnetic noise from the solder portions 37 to the external connector 45 is suppressed more reliably, and electromagnetic noise entering from the external connector 45 is suppressed more reliably from being radiated from the solder portions 37 inside the housing 11.

In the fifth modification shown in FIG. 7, the elastic member 66 may be interposed between the lid member 13 and the fastened portion 52, for example. In other words, the shield member 50 may be connected to the lid member 13 via the elastic member 66.

In the fifth modification shown in FIG. 7, the elastic member 66 may be, for example, a spring member having conductivity.

The shield member 50 may cover the bent portion 44 and the housing connector body 41 in addition to the solder portions 37 of the housing connector terminals 42. In other words, in the housing connector 40, it suffices if at least the solder portions 37 of the housing connector terminals 42 are covered by the shield member 50.

For example, the fastened portion 52 may be fastened to the housing 11 together with the ground pattern section 23 by a press-fit pin.

In the shield member 50, the fastened portion 52 does not necessarily need to be fastened to the housing 11 together with the ground pattern section 23. For example, the fastened portion 52 may be fastened to the housing 11 separately from the ground pattern section 23.

The component terminals 29 and the housing connector terminals 42 may be electrically connected to the corresponding conductor patterns 20 by press-fitting.

The number of the component terminals 29 of the electronic component 27 is not particularly limited.

The electronic component 27 does not necessarily need to be a discrete semiconductor element having multiple component terminals 29, including both high-voltage terminals and low-voltage terminals. For example, the electronic component 27 may be a semiconductor element including multiple component terminals 29 that are all high-voltage terminals.

The vehicle on-board electrical device 10 does not necessarily need to include the shield plate 31.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A vehicle on-board electrical device, comprising:
a box-shaped housing;
a circuit board accommodated in the housing;
an electronic component having a component body and a component terminal; and
a housing connector including a housing connector body and a housing connector terminal, wherein
a conductor pattern forming an electrical circuit is formed on the circuit board,
electromagnetic noise is radiated from the electronic component,
the component body is configured to function as a component of the electrical circuit,
the component terminal is configured to mount the component body to the conductor pattern,
the housing connector body is provided on the housing so as to allow an external connector to be connected to the housing connector body from outside the housing,
the housing connector terminal is configured to mount the housing connector body to the conductor pattern,
the component terminal includes a first electrical connection portion electrically connected to the conductor pattern,
the housing connector terminal includes a second electrical connection portion electrically connected to the conductor pattern,
the vehicle on-board electrical device further comprises a shield member made of a metal plate, and
in the housing connector, at least the second electrical connection portion of the housing connector terminal is covered by the shield member.

2. The vehicle on-board electrical device according to claim 1, wherein
the circuit board has a first surface and a second surface,
the first electrical connection portion is a first solder portion connected to the conductor pattern by solder on a first-surface side,
the second electrical connection portion is a second solder portion connected to the conductor pattern by solder on the first-surface side,
the housing connector terminal is a thin plate-shaped connector lead that connects the housing connector body to the conductor pattern,
the connector lead extends through the circuit board from the second surface to the first surface,
the connector lead includes a connector projection that projects from the conductor pattern in a direction from the second surface toward the first surface and includes the second solder portion, and
the shield member includes a shield projection projecting in a direction away from the conductor pattern so as to accommodate the second solder portion.

3. The vehicle on-board electrical device according to claim 1, wherein the housing connector terminal includes a communication line configured to communicate with an external higher-level ECU connected to the external connector.

4. The vehicle on-board electrical device according to claim 2, wherein
the connector lead includes a bent portion extending from the connector projection toward the housing connector body on a second-surface side,
the shield member includes a solder portion shield section covering the second solder portion of the housing connector terminal, and a bent portion shield section made of a metal plate covering the bent portion, and
the solder portion shield section is provided on an opposite side of the circuit board from the bent portion shield section.

5. The vehicle on-board electrical device according to claim 1, wherein
the conductor pattern includes a ground pattern section, and
the shield member includes:
a first fastened portion fastened to the housing together with the ground pattern section; and
a second fastened portion extending from the first fastened portion toward the housing and fastened to the housing with a bolt.

6. The vehicle on-board electrical device according to claim 1, wherein the shield member is connected to the housing via a conductive tape.

7. The vehicle on-board electrical device according to claim 1, wherein
the housing includes a protrusion protruding toward an inside of the housing, and
the shield member includes a spring portion that is pressed against the protrusion.

8. The vehicle on-board electrical device according to claim 1, wherein
the housing includes a housing body with an opening, and a lid member covering the opening, and
the shield member is connected to the lid member via an elastic member having conductivity.

9. The vehicle on-board electrical device according to claim 2, wherein
the electrical circuit includes a high-voltage circuit section connected to a high-voltage battery, and a low-voltage circuit section having a lower voltage than the high-voltage circuit section,
the conductor pattern includes a high-voltage pattern section forming the high-voltage circuit section and a low-voltage pattern section forming the low-voltage circuit section,
the high-voltage pattern section and the low-voltage pattern section are insulated from each other on the first-surface side of the circuit board,
a shield plate made of a metal plate is provided between the component body of the electronic component and the second surface of the circuit board, the shield plate facing the second surface of the circuit board and being connected to the housing,
the connector projection of the housing connector terminal includes a low-voltage solder portion soldered to the low-voltage pattern section,
the component terminal is a thin plate-shaped component lead that connects the component body to the high-voltage pattern section,
the component lead is provided so as not to interfere with the shield plate, and extends through the circuit board from the second surface to the first surface,
the component lead includes a component lead projection that projects beyond the high-voltage pattern section in a direction from the second surface toward the first surface, and
the component lead projection includes a high-voltage solder portion soldered to the high-voltage pattern section.
